(19) United States
(12) Patent Application Publication
(10) Pub. No.: US 2012/0228014 A1
(43) Pub. Date: Sep. 13, 2012

(54) CIRCUITIZED SUBSTRATE WITH INTERNAL THIN FILM CAPACITOR AND METHOD OF MAKING SAME

(75) Inventors: Rabindra N. Das, Vestal, NY (US); Mark D. Poliks, Vestal, NY (US); Voya R. Markovich, Endwell, NY (US); Peter A. Moschak, Chenango Forks, NY (US)

(73) Assignee: Endicott Interconnect Technologies, Inc., Endicott, NY (US)

(21) Appl. No.: 13/042,578

(22) Filed: Mar. 8, 2011

(51) Int. Cl. H05K 1/16; B05D 5/12

(52) U.S. Cl. 174/260; 427/99.2

(57) ABSTRACT

A circuitized substrate for use in such electrical structures as information handling systems wherein the substrate includes a capacitive substrate as part thereof. The capacitive substrate includes a thin film layer of capacitive material strategically positioned on a conductive layer relative to added electrically conductive elements to in turn provide a plurality of internal capacitors within the final circuitized substrate during operation thereof. A method of making such a circuitized substrate is also provided.

### FIELD OF THE INVENTION

The invention relates to circuitized substrates and, more particularly, to such substrates including at least one internal capacitor as part thereof.

### BACKGROUND OF THE INVENTION

It is known in the art that circuitized substrates such as printed circuit boards (hereinafter also referred to as PCBs), chip carriers, and the like are typically constructed in laminate form in which several layers of dielectric material and conductive material (laminates) are bonded together using relatively high temperature and pressure lamination processes. The conductive layers, typically of thin copper, are usually used in the formed substrate for providing electrical connections to and among various electrical components such as integrated circuits (semiconductor chips) and discrete passive devices, such as capacitors, resistors, inductors, and the like, typically positioned on the outer surface(s) of the final substrate.

Mounting electrical components on the external surfaces of PCBS and other substrates is known. Some of the conductors, e.g., lines (traces) used to interconnect the components, may also be printed on the surface. The inner layers are primarily used to interconnect the components through other conductors printed on these inner layers and conductive openings passing through the outer and selected ones of the inner layers. For complex circuits, the surface area must be carefully allocated to fit the many requisite components. Also, in the case of capacitor components, it is desirable to position some of the capacitors near other, associated components to minimize path length and thereby minimize parasitic inductance. It is known, for example, to form a discrete capacitor from a bottom aluminum electrode, a next layer of tantalum, a next layer of tantalum oxide serving as a dielectric, and a top electrode layer. This capacitor may be mounted on the surface of a PCB, and two conductive openings passed through the PCB to connect to the two electrodes. This capacitor was not part of a printed circuit board, but instead was a surface component on a substrate.

Unfortunately, many discrete passive devices occupy a high percentage of the surface area of the completed substrate, which is undesirable from a future design aspect because of the increased need and demand for miniaturization in today's substrates and products containing same art. In order to increase the available substrate surface area (also often referred to as “real estate”), there have been a variety of efforts to include multiple functions (e.g. resistors, capacitors and the like) on a single component for mounting on a board. When passive devices are in such a configuration, these are often referred to collectively and individually as integral passive devices or the like, meaning that the functions are integrated into the singular component. Because of such external positioning, these components still utilize, albeit less than if in singular form, board real estate.

In response, there have also been efforts to embed discrete passive components within the substrate itself, such components often then referred to as embedded passive components. A capacitor designed for disposition within (between selected layers of) a circuitized substrate may thus be referred to as an embedded integral passive component, such as, for example, an embedded capacitor. Such a capacitor thus provides internal capacitance. The result of this internal positioning is that it is unnecessary to also position such devices externally on the PCB's outer surface(s), thus saving valuable PCB real estate.

For a fixed capacitor area, two known approaches are available for increasing the planar capacitance (capacitance/area) of an internal capacitor. In one such approach, higher dielectric constant materials can be used, while in a second, the thickness of the dielectric can be reduced. These constraints are reflected in the following formula, known in the art, for capacitance per area: C/A=(Dielectric Constant of the Laminate times the Dielectric Constant in Vacuum/Dielectric Thickness) where: C is the capacitance and A is the capacitor's area. The following patents describe various substrate structures, some including internal capacitors as part thereof. Some of the patents listed below also mention use of various materials for providing desired capacitance levels under the above formula, and many mention or suggest problems associated with the methods and resulting materials used to do so. The listing of these documents is not an admission that any are prior art to the instantly claimed invention nor that an exhaustive search has been completed.

In U.S. Pat. No. 7,541,265, issued to Das et al. on Jun. 2, 2009 for CAPACITOR MATERIAL FOR USE IN CIRCUITIZED SUBSTRATES, CIRCUITIZED SUBSTRATE UTILIZING SAME, METHOD OF MAKING SAID CIRCUITIZED SUBSTRATE, AND INFORMATION HANDLING SYSTEM UTILIZING SAID CIRCUITIZED SUBSTRATE, there is described a material for use as part of an internal capacitor within a circuitized substrate. The material includes a polymer (e.g., a cycloaliphatic epoxy or phenoxy based) resin and a quantity of nano-powders of ferroelectric ceramic material (e.g., barium titanate) having a particle size substantially in the range of from about 0.01 microns to about 0.90 microns and a surface area for selected ones of said particles within the range of from about 2.0 to about 20 square meters per gram.

In U.S. Pat. No. 7,449,381, issued to Das et al. on Nov. 11, 2008 for METHOD OF MAKING A CAPACITIVE SUBSTRATE FOR USE AS PART OF A LARGER CIRCUITIZED SUBSTRATE, METHOD OF MAKING SAID CIRCUITIZED SUBSTRATE AND METHOD OF MAKING AN INFORMATION HANDLING SYSTEM INCLUDING SAID CIRCUITIZED SUBSTRATE, there is described a method of forming a capacitive substrate in which at least one capacitive dielectric layer of material is screen or ink jet printed onto a conductor and the substrate is thereafter processed further. Thru-holes couple selected elements within the substrate to form at least two capacitors as internal elements of the substrate.

In U.S. Pat. No. 7,429,510, issued to Das et al. on Sep. 30, 2008 for METHOD OF MAKING A CAPACITIVE SUBSTRATE USING PHOTOIMAGEABLE DIELECTRIC FOR USE AS PART OF A LARGER CIRCUITIZED SUBSTRATE, METHOD OF MAKING SAID CIRCUITIZED SUBSTRATE AND METHOD OF MAKING AN INFORMATION HANDLING SYSTEM INCLUDING SAID CIRCUITIZED SUBSTRATE, there is described a method of forming a capacitive substrate in which at least one capacitive dielectric layer of material is screen or ink jet printed onto a conductor and the substrate is thereafter processed further. Thru-holes couple selected elements within the substrate to form at least two capacitors as internal elements of the substrate. Photo-imageable material is used to facilitate positioning of the capacitive dielectric being printed.

In U.S. Pat. No. 7,384,856, issued to Das et al. on Jun. 10, 2008 for METHOD OF MAKING AN INTERNAL CAPACITIVE SUBSTRATE FOR USE IN A CIRCUITIZED SUBSTRATE AND METHOD OF MAKING SAID CIRCUITIZED SUBSTRATE, there is described a method of forming a capacitive substrate in which first and second conductors are formed opposite a dielectric, with one of these electrically coupled to a thru-hole connection. Each functions as an electrode for the resulting capacitor. The substrate is then adapted for being incorporated within a larger structure to form a circuitized substrate such as a printed circuit board or a chip carrier. Additional capacitors are also possible.

In U.S. Pat. No. 7,161,810, issued to Fraley et al. on Jan. 9, 2007 for STACKED CHIP ELECTRONIC PACKAGE HAVING LAMINATE CARRIER AND METHOD OF MAKING SAME, there is described a multi-chip electronic package which utilizes an organic, laminate chip carrier and a pair of semiconductor chips positioned on an upper surface of the carrier in a stacked orientation. The organic, laminate chip carrier comprises a plurality of conductive planes and dielectric layers and couples one or both of the chips to underlying conductors on the bottom surface thereof. The carrier may include an internal capacitor for enhanced operational capabilities.

In U.S. Pat. No. 7,035,113, issued to Fraley et al. on Apr. 25, 2006 for MULTI-CHIP ELECTRONIC PACKAGE HAVING LAMINATE CARRIER AND METHOD OF MAKING SAME, there is described a multi-chip electronic package which utilizes an organic, laminate chip carrier and a plurality of semiconductor chips positioned on an upper surface of the carrier. The organic, laminate chip carrier comprises a plurality of conductive planes and dielectric layers and couples the chips to underlying conductors on the bottom surface thereof. The carrier may include an internal capacitor for enhanced operational capabilities.

In U.S. Pat. No. 7,025,607, issued to Das et al. on Apr. 11, 2006 for CAPACITOR MATERIAL WITH METAL COMPONENT FOR USE IN CIRCUITIZED SUBSTRATES, CIRCUITIZED SUBSTRATE UTILIZING SAME, METHOD OF MAKING SAID CIRCUITIZED SUBSTRATE, AND INFORMATION HANDLING SYSTEM UTILIZING SAID CIRCUITIZED SUBSTRATE, there is described a material for use as part of an internal capacitor within a circuitized substrate. A polymer resin and a quantity of nano-powders includes a mixture of at least one metal component and at least one ferroelectric ceramic component. The ferroelectric ceramic component nano-particles have a particle size substantially in the range of between about 0.01 microns and about 0.9 microns and a surface within the range of from about 2.0 to about 20 square meters per gram.

In U.S. Pat. No. 7,023,707, issued to Fraley et al. on Apr. 4, 2006 for INFORMATION HANDLING SYSTEM, there is described an information handling system, e.g., computer, server or mainframe, which includes a multi-chip electronic package utilizing an organic, laminate chip carrier and a plurality of semiconductor chips positioned on an upper surface of the carrier. The organic, laminate chip carrier comprises a plurality of conductive planes and dielectric layers and couples the chips to underlying conductors on the bottom surface thereof. The carrier may include an internal capacitor for enhanced operational capabilities of the final system product.

In U.S. Pat. No. 6,992,896, issued to Fraley et al. on Jan. 31, 2006 for STACKED CHIP ELECTRONIC PACKAGE HAVING LAMINATE CARRIER AND METHOD OF MAKING SAME, there is described a multi-chip electronic package which utilizes an organic, laminate chip carrier and a pair of semiconductor chips positioned on an upper surface of the carrier in a stacked orientation. The organic, laminate chip carrier comprises a plurality of conductive planes and dielectric layers and couples one or both of the chips to underlying conductors on the bottom surface thereof. The carrier may include an internal capacitor for enhanced operational capabilities.

In U.S. Pat. No. 6,704,207, issued to Kopf on Mar. 9, 2004 for DEVICE AND METHOD FOR INTERSTITIAL COMPONENTS IN A PRINTED CIRCUIT BOARD, there is described a printed circuit board which includes a first layer having first and second surfaces, with an above-board device (e.g., an ASIC chip) mounted thereon. The PCB includes a second layer having third and fourth surfaces. One of the surfaces can include a recessed portion for securely holding an interstitial component. A “via,” electrically connecting the PCB layers, is also coupled to a lead of the interstitial component. The described interstitial components include components such as diodes, transistors, resistors, capacitors, thermocouples, and the like.

In U.S. Pat. No. 6,616,794, issued to Hartman et al. on Sep. 9, 2003 for INTEGRAL CAPACITANCE FOR PRINTED CIRCUIT BOARD USING DIELECTRIC NANOPOWDERS, there is described a method for producing integral capacitance components for inclusion within printed circuit boards in which hydro-thermally prepared nano-powders permit the fabrication of dielectric layers that offer increased dielectric constants and are readily penetrated by micro-vias. In the method described in this patent, a slurry or suspension of a hydro-thermally prepared nano-powder and solvent is prepared. A suitable bonding material, such as a polymer, is mixed with the nano-powder slurry, to generate a composite mixture which is formed into a dielectric layer. The dielectric layer may be placed upon a conductive layer prior to curing, or conductive layers may be applied upon a cured dielectric layer, either by lamination or metallization processes, such as vapor deposition or sputtering.

In U.S. Pat. No. 6,544,651, issued to Wong et al. on Apr. 8, 2003 for HIGH DIELECTRIC CONSTANT NANO-STRUCTURE POLYMER-CERAMIC COMPOSITE, there is described a polymer-ceramic composite having high dielectric constants formed using polymers containing a metal acetylacetonate (acac) curing catalyst. In particular, a certain percentage of Co (III) may increase the dielectric constant of a certain epoxy. The high dielectric polymers are combined with fillers, preferably ceramic fillers, to form two phase composites having high dielectric constants. Composites having about 30% to about 90% volume ceramic loading and a high dielectric base polymer, preferably epoxy, were apparently found to have dielectric constants greater than about 60. Composites having dielectric constants greater than about 74 to about 150 are also mentioned in this patent. Also mentioned are embedded capacitors with specific capacitance densities.

In U.S. Pat. No. 6,524,352, issued to Adae-Amoakoh et al. on Feburary 25, 2003 for METHOD OF MAKING A PARALLEL CAPACITOR LAMINATE, there is defined a parallel capacitor structure capable of forming an internal part of a larger circuit board to provide capacitance therefor. Alternatively, the capacitor may be used as an interconnector to interconnect two different electronic components (e.g., chip carriers, circuit boards, and semiconductor chips) while still providing desired levels of capacitance for one or more of said components. The capacitor includes at least one internal conductive layer, two additional conductor layers added on opposite sides of the internal conductor, and inorganic dielectric material (preferably an oxide layer on the second conductor layer's outer surfaces or a suitable dielectric material such as barium titanate applied to the second conductor layers). Further, the capacitor includes outer conductor layers atop the inorganic dielectric material, thus forming a parallel capacitor between the internal and added conductive layers and the outer conductors.

In U.S. Pat. No. 6,446,317, issued to Figueroa et al. on Sep. 10, 2002 for HYBRID CAPACITOR AND METHOD OF FABRICATION THEREFOR, there is described a hybrid capacitor associated with an integrated circuit package that provides multiple levels of excess, off-chip capacitance to die loads. The hybrid capacitor includes a low inductance, parallel plate capacitor which is embedded within the package and electrically connected to a second source of off-chip capacitance. The parallel plate capacitor is disposed underneath a die, and includes a top conductive layer, a bottom conductive layer, and a thin dielectric layer that electrically isolates the top and bottom layers. The second source of off-chip capacitance is a set of self-aligned via capacitors, and/or one or more discrete capacitors, and/or an additional parallel plate capacitor. Each of the self-aligned via capacitors is embedded within the package, and has an inner conductor and an outer conductor. The inner conductor is electrically connected to either the top or bottom conductive layer, and the outer conductor is electrically connected to the other conductive layer. The discrete capacitors are electrically connected to contacts from the conductive layers to the surface of the package. During operation, one of the conductive layers of the low inductance parallel plate capacitor provides a ground plane, while the other conductive layer provides a power plane.

In U.S. Pat. No. 6,395,996, issued to Tsai et al. on May 28, 2002 for MULTI-LAYERED SUBSTRATE WITH A BUILT-IN CAPACITOR DESIGN, there is described a multi-layered substrate having built-in capacitors which are used to decouple high frequency noise generated by voltage fluctuations between a power plane and a ground plane of a multi-layered substrate. At least one kind of dielectric material, which has filled-in through holes between the power plane and the ground plane and includes a high dielectric constant, is used to form the built-in capacitors.

In U.S. Pat. No. 6,370,012, issued to Adae-Amoakoh et al. on Apr. 9, 2002 for CAPACITOR LAMINATE FOR USE IN PRINTED CIRCUIT BOARD AND AS AN INTERCONNECTOR, there is described a parallel capacitor structure capable of forming an internal part of a larger circuit board to provide capacitance there-for. Alternatively, the capacitor may be used to interconnect two different electronic components (e.g., chip carriers, circuit boards, and even semiconductor chips) while still providing desired levels of capacitance for one or more of said components. The capacitor includes at least one internal conductive layer, two additional conductor layers added on opposite sides of the internal conductor, and inorganic dielectric material (preferably an oxide layer on the second conductor layer's outer surfaces or a suitable dielectric material such as barium titanate applied to the second conductor layers). Further, the capacitor includes outer conductor layers atop the inorganic dielectric material, thus forming a parallel capacitor between the internal and added conductive layers and the outer conductors.

In U.S. Pat. No. 6,207,595, issued to Appelt et al. on Mar. 27, 2001 for LAMINATE AND METHOD OF MANUFACTURE THEREOF, there is described a fabric-resin dielectric material for use in a laminate structure and method of its manufacture. The resulting structure is adaptable for use in a printed circuit board or chip carrier substrate. The resin may be an epoxy such as is currently used on a large scale worldwide for “FR4” composites. A resin material based on bismaleimide-triazine (BT) is also acceptable. More preferably, the resin is a phenolically hardenable resin material as is known in the art, with a glass transition temperature of about 145 degrees Celsius.

In U.S. Pat. No. 6,150,456, issued to Lee et al. on Nov. 21, 2000 for HIGH DIELECTRIC CONSTANT FLEXIBLE POLYIMIDE FILM AND PROCESS OF PREPARATION, there is described a flexible, high dielectric constant polyimide film composed of either a single layer of an adhesive thermoplastic polyimide film or a multilayer polyimide film having adhesive thermoplastic polyimide film layers. These film layers are bonded to one or both sides of the film and having dispersed in at least one of the polyimide layers from 4% to 85% weight percentage of a ferroelectric ceramic filler, such as barium titanate or polyimide-coated barium titanate, and having a dielectric constant of from 4 to 60. The high dielectric constant polyimide film can be used in electronic circuitry and electronic components such as buried (internal) film capacitors.

In U.S. Pat. No. 6,084,306, issued to Yew et al. on Jul. 4, 2000 for BRIDGING METHOD OF INTERCONNECTS FOR INTEGRATED CIRCUIT PACKAGES, there is described an integrated circuit package having first and second layers, a plurality of routing pads being integral with the first layer, a plurality of upper and lower conduits respectively disposed on the upper and lower surfaces of the first layer. One of the upper conduits is electrically connected to one of the lower conduits. A plurality of pads is disposed on the second layer. Vias (holes) electrically connect the pads to the lower conduits and a chip is adhered to the second layer having bonding pads, at least one of which is electrically connected to one of the routing pads.

In U.S. Pat. No. 6,068,782, issued to Brandt et al. on May 30, 2004 for INDIVIDUAL EMBEDDED CAPACITORS FOR LAMINATED PRINTED CIRCUIT BOARDS, there is described a method of fabricating individual, embedded capacitors in multilayer printed circuit boards. The method is allegedly compatible with standard printed circuit board fabrication techniques. The capacitor fabrication is based on a sequential build-up technology employing a first pattern-able insulator. After patterning of the insulator, pattern grooves are filled with a high dielectric constant material, typically a polymer/ceramic composite. Capacitance values are defined by the pattern size, thickness and dielectric constant of the composite. Capacitor electrodes and other electrical circuitry can be created either by etching laminated copper, by metal evaporation, or by depositing conductive ink.

In U.S. Pat. No. 5,796,587, issued to Lauffer et al. on Aug. 18, 1998 for PRINTED CIRCUT BOARD WITH EMBEDDED DECOUPLING CAPACITANCE AND METHOD FOR PRODUCING SAME, there is described a method for producing a capacitor to be embedded in an electronic circuit package comprising the steps of selecting a first conductor foil, selecting a dielectric material, coating the dielectric material on at least one side of the first conductor foil, and layering the coated foil with a second conductor foil on top of the coating of dielectric material. Also claimed is an electronic circuit package incorporating at least one embedded capacitor manufactured in accordance with the present invention.

In U.S. Pat. No. 5,280,192, issued to Kryzaniwsky on Jan. 18, 1994 for THREE-DIMENSIONAL MEMORY CARD STRUCTURE WITH INTERNAL DIRECT CHIP ATTACHMENT, there is described a card structure which includes an internal three dimensional array of implanted semiconductor chips. The card structure includes a power core and a plurality of chip cores. Each chip core is joined to the power core on opposite surfaces of the power core, and each chip core includes a compensator core having a two dimensional array of chip wells. Each chip well allows for a respective one of the semiconductor chips to be implanted therein. Further, a compliant dielectric material is disposed on the major surfaces of the compensator core except at the bottoms of the chip wells. The compliant dielectric material has a low dielectric constant and has a thermal coefficient of expansion compatible with those of the semiconductor chips and the compensator core, so that thermal expansion stability with the chips and the compensator core is maintained.

In U.S. Pat. No. 5,162,977, issued to Paurus et al. on Nov. 10, 1992 for PRINTED CIRCUIT BOARD HAVING AN INTEGRATED DECOUPLING CAPACITIVE ELEMENT, there is described a PCB which includes a high capacitance power distribution core, the manufacture of which is compatible with standard printed circuit board assembly technology. The high capacitance core consists of a ground plane and a power plane separated by a planar element having a high dielectric constant. The high dielectric constant material is typically glass fiber impregnated with a bonding material, such as epoxy resin loaded with a ferro-electric ceramic substance having a high dielectric constant. The ferro-electric ceramic substance is typically a nano-powder combined with an epoxy bonding material. According to this patent, the resulting capacitance of the power distribution core is sufficient to eliminate the need for decoupling capacitors on a PCB.

In U.S. Pat. No. 5,099,309, issued to Kryzaniwsky on Mar. 24, 1992 for THREE-DIMENSIONAL MEMORY CARD STRUCTURE WITH INTERNAL DIRECT CHIP ATTACHMENT, there is described a memory card structure containing an embedded three dimensional array of semiconductor memory chips. The card structure includes at least one memory core and at least one power core which are joined together in an overlapping relationship. Each memory core comprises a copper-invar-copper (CIC) thermal conductor plane having a two dimensional array of chip well locations on each side of the plane. Polytetrafluoroethylene (PTFE) covers the major surfaces of the thermal conductor plane except at the bottoms of the chip wells. Memory chips are placed in the chip wells and are covered by insulating and wiring levels. Each power core comprises at least one CIC electrical conductor plane and PTFE covering the major surfaces of the electrical conductor plane. Provision is made for providing electrical connection pathways and cooling pathways along vertical as well as horizontal planes internal to the card structure.

In U.S. Pat. No. 5,079,069, issued to Howard et al. on Jan. 7, 1992 for CAPACITOR LAMINATE FOR USE IN CAPACITIVE PRINTED CIRCUIT BOARDS AND METHODS OF MANUFACTURE, there is described a capacitor laminate which allegedly serves to provide a bypass capacitive function for devices mounted on the PCB, the capacitor laminate being formed of conventional conductive and dielectric layers. Each individual external device is allegedly provided with capacitance by a proportional portion of the capacitor laminate and by borrowed capacitance from other portions of the capacitor laminate, the capacitive function of the capacitor laminate being dependent upon random firing or operation of the devices. The resulting PCB still requires the utilization of external devices thereon, and thus does not afford the PCB external surface area real estate savings which are desired and demanded in today's technology.

In U.S. Pat. No. 5,016,085, issued to Hubbard et al. on May 14, 1991 for HERMETIC PACKAGE FOR INTEGRATED CIRCUIT CHIPS, there is described a hermetic package which has an interior recess for holding a semiconductor chip. The recess is square and set at 45 degrees with respect to the rectangular exterior of the package. The package uses ceramic layers which make up the package's conductive planes with the interior opening stepped to provide connection points. The lowest layer having a chip opening therein may be left out of the assembly to provide a shallower chip opening recess. This of course is not the same as an internally formed capacitance or semiconductor component of the nature described above, but it does mention internal ceramic layers for a specified purpose as part of an internal structure.

With particular respect to commercially available dielectric powders which have been used in internal conductive structures such as mentioned in some of the above patents, some of these powders are known to be produced by a high-temperature, solid-state reaction of a mixture of the appropriate stoichiometric amounts of oxides or oxide precursors (e.g., carbonates, hydroxides or nitrates) of barium, calcium, titanium, and the like. In such calcination processes, the reactants are wet-milled to accomplish a desired final mixture. The resulting slurry is dried and fired at elevated temperatures, sometimes as high as 1,300 degrees Celsius, to attain the desired solid state reactions. Thereafter, the fired product is milled to produce a powder.

Although the pre-fired and ground dielectric formulations produced by solid phase reactions are acceptable for some electrical applications, these suffer from several disadvantages. First, the milling step serves as a source of contaminants, which can adversely affect electrical properties. Second, the milled product consists of irregularly shaped fractured aggregates which are often too large in size and possess a wide particle size distribution, 500-20,000 nm. Consequently, films produced using these powders are limited to thicknesses greater than the size of the largest particle. Thirdly, powder suspensions or composites produced using pre-fired ground ceramic powders must be used immediately after dispersion, due to the high sedimentation rates associated with large particles. For example, the stable crystalline phase of barium titanate particles greater than 200 nm is tetragonal and, at elevated temperatures, a large increase in dielectric constant occurs due to a phase transition.

It is thus clear that methods of making PCBs which rely on the advantageous features of using nano-powders as part of the PCB's internal components or the like, such as those described in selected ones of the above patents, may possess various undesirable aspects which are detrimental to providing a PCB with optimal functioning capabilities when it comes to internal capacitance or other electrical operation. This is particularly true when the desired final product attempts to meet today's miniaturization demands, including the utilization of high density patterns of thru-holes therein.

The circuitized substrate as defined herein includes one or more thin film internal (embedded) capacitors to thereby enhance the overall operational capabilities of the substrate while saving precious external surface real estate which may then be used for other components, circuitry, etc. Use of such thin film capacitors also serves to assure that many thickness dimensions of various parts of the final structure are kept to a minimum. As further defined herein, a new and unique method of making such a circuitized substrate is provided in which the method can be performed in a facile manner using, for the most part, conventional substrate processes. It is believed that such a circuitized substrate and such a method of making same constitute significant advancements in the art.

### SUMMARY OF THE INVENTION

It is, therefore, a primary object of the present invention to enhance the circuitized substrate art by providing a circuitized substrate having the advantageous features taught herein, including an internal thin film capacitor as part thereof.

It is another object of the invention to provide a method of making such a circuitized substrate which can be accomplished in a relatively facile manner and at relatively low costs.

According to one aspect of this invention, there is provided a circuitized substrate comprising a capacitive substrate including at least one electrically conductive layer, a thin film layer of capacitor material on the electrically conductive layer and at least one electrically conductive element positioned on a first surface of the thin film layer adjacent the electrically conductive layer, and at least one dielectric layer positioned on the capacitive substrate, the electrically conductive layer, thin film layer of capacitor material and electrically conductive element forming a first capacitor within the circuitized substrate during operation thereof.

According to another aspect of this invention, there is provided a method of making a circuitized substrate comprising providing an electrically conductive layer including upper and lower opposing surfaces, depositing a thin film layer of capacitor material on these upper and lower opposing surfaces, bonding a pair of electrically conductive elements to the thin film layer of capacitor material, a first of these electrically conductive elements being located on the capacitor material on the upper opposing surface and the second electrically conductive element located on the capacitor material on the lower opposing surface of the electrically conductive layer to form a capacitive substrate including the electrically conductive layer, the thin film layer of capacitor material on the upper and lower opposing surfaces of the electrically conductive layer and the electrically conductive elements, and bonding at least one dielectric layer on the capacitive substrate to substantially cover the first and/or second electrically conductive elements.

### BRIEF DESCRIPTION OF THE DRAWINGS

A complete understanding of the present invention may be obtained by reference to the accompanying drawings, when considered in conjunction with the subsequent, detailed description, in which:

FIGS. 1 through 4 are partial side elevational views, in section, which illustrate the steps of forming a capacitive substrate for use in a circuitized substrate according to one aspect of this invention;

FIG. 4a is a side elevational view, in section, of a circuitized substrate including the capacitive substrate of FIGS. 1 through 4 therein, this circuitized substrate being shown positioned on and coupled to a hosting substrate and further including a plurality of electrical components positioned thereon; and

FIGS. 5 through 8 are side elevational views, in section, illustrating the steps of forming a circuitized substrate including the capacitive substrate of FIG. 4 (excluding the thru-hole) according to one aspect of this invention.

### DETAILED DESCRIPTION OF THE PREFERRED EMBODIMENT

For a better understanding of the present invention, together with other and further objects, advantages, and capabilities thereof, reference is made to the following disclosure and appended claims in connection with the above-described drawings. It is understood that like numerals may be used to indicate like elements from Figure to Figure.

### DEFINITIONS

The following terms will be used herein and are understood to have the meanings associated therewith.

By the term “capacitive substrate” as used herein is meant to define a structure including at least one electrically conductive layer, a quantity of capacitive material on this conductive layer, and at least two additional conductive elements (e.g., conductive lines and/or pads) so as to form at least two capacitors when the capacitive substrate is incorporated within and utilized as part of a circuitized substrate.

By the term “circuit” as used herein is meant a pattern of electrical conductors, selected ones of these electrical conductors being electrically interconnected by circuit lines (also referred to in the industry as “traces”). Typically, such circuits are comprised of copper or copper alloys, but this invention is not limited to these materials.

By the term “circuitized substrate” as used herein is meant to define a structure including at least one dielectric layer having at least one surface having thereon at least one circuit. Examples of dielectric materials suitable for use in such structures include fiberglass-reinforced or non-reinforced epoxy resins (sometimes referred to simply as FR4 material, meaning its Flame Retardant rating), poly-tetrafluoroethylene (Teflon), polyimides, polyamides, cyanate resins, photoimageable materials, and other like materials, or combinations thereof. Examples of electrically conductive materials for the circuit layers include copper or copper alloy. If the dielectric is a photoimageable material, it is photo-imaged or photo-patterned, and developed to reveal the desired circuit pattern, including the desired opening(s) as defined herein, if required. The dielectric material may be curtain coated or screen applied, or it may be supplied as a dry film or in other sheet form. The term “circuitized substrate” as used herein is not meant to define a capacitive structure as defined herein which is adapted for being embedded within and thus part of the overall larger circuitized substrate.

By the term “electronic package” as used herein is meant to include at least one and possibly more such circuitized substrates having one or more electrical components as part thereof.

By the term “electrical component” as used herein is meant components such as semiconductor chips, modules, resistors, capacitors and the like, which are typically adapted for being positioned on and electrically coupled to the external conductors of the circuits of such substrates, and electrically coupled to other components (if utilized). The circuitized substrates taught herein are readily adaptable for having one or more such electrical components positioned thereon and electrically coupled thereto. The term “electrical component” as used herein is not meant to define a capacitive structure as defined herein which is adapted for being embedded within and thus part of the overall larger circuitized substrate and, in some instances, electrically coupled to one or more such electrical components.

By the term “high density” as used herein to define the pattern of electrical conductors of the substrate and electronic device circuitry is meant a pattern wherein the conductors each possess a maximum width within the range of from only about 0.2 mils to about 1.0 mil and are spaced apart from each other (at the nearest point of edges of adjacent conductor features) within the range of only about 0.2 mils to about 1.0 mil (as defined herein, a mil is equal to 0.001 inch).

By the term “high speed” as used herein to define the signal speeds possible within the circuitized substrates of the invention is understood to mean signals within a frequency range of from about 3.0 to about 10.0 Gigabits Per Second (GPS) and possibly even faster.

By the term “information handling system” as used herein is meant to define any instrumentality or aggregate of instrumentalities primarily designed to compute, classify, process, transmit, receive, retrieve, originate, switch, store, display, manifest, measure, detect, record, reproduce, handle or utilize any form of information, intelligence or data for business, scientific, control or other purposes. Examples include personal computers and larger processors such as computer servers and mainframes. Such products are well known in the art and are also known to include electronic packages including PCBs and chip carriers and other forms of circuitized substrates as part thereof, some including several such packages depending on the operational requirements thereof.

By the term “thick film” to define the thickness of the film layers of capacitance material used in the invention is meant a film having a thickness of from about fifteen microns to about thirty-five microns.

By the term “thin film” to define the thickness of the film layers of capacitance material used in the invention is meant a film having a thickness of from about only about 0.01 micron to about ten microns.

By the term “silicon oxide” is meant silicon dioxide (SiO₂) or silicon monoxide (SiO). The chemical compound silicon dioxide, also known as silica, is most commonly found in nature as sand or quartz, as well as in the cell walls of diatoms.

By the term “anodizing” is meant an electrolytic passivation process used to increase the thickness of the oxide layer on the surface of metal parts. The process is called “anodizing” because the part to be treated forms the anode electrode of an electrical circuit.

By the term “self-assembly” is meant processes in which a disordered system of pre-existing components forms an organized structure or pattern as a consequence of specific, local interactions among the components themselves, without external direction.

By the term “thru-hole” as used herein to define an electrically conductive structure formed within a circuitized substrate as defined herein is meant to include three different types of electrically conductive elements. It is known in multilayered PCB'S and chip carriers to provide various conductive interconnections between various conductive layers of the PCB and carrier. For some applications, it is desired that electrical connection be made with almost if not all of the conductive layers. In such a case, thru-holes are typically provided through the entire thickness of the board, in which case these are often also referred to as “plated thru holes” or PTHS. For other applications, it is often desired to also provide electrical connection between the circuitry on one face of the circuitized substrate to a depth of only one or more of the inner circuit layers. These are referred to as “blind vias”, which pass only part way through (into) the substrate. In still another case, such multilayered substrates often require internal connections (“vias”) which are located entirely within the substrate and covered by external layering, including both dielectric and conductive. Such internal “vias”, also referred to as “buried vias”, may be formed within a first circuitized substrate which is then bonded to other substrates and/or dielectric and/or conductive layers to form the final, multilayered embodiment. For purposes of this application, the term “thru-hole”, when defining conductive openings in a circuitized substrate, is meant to include all three types of such electrically conductive openings.

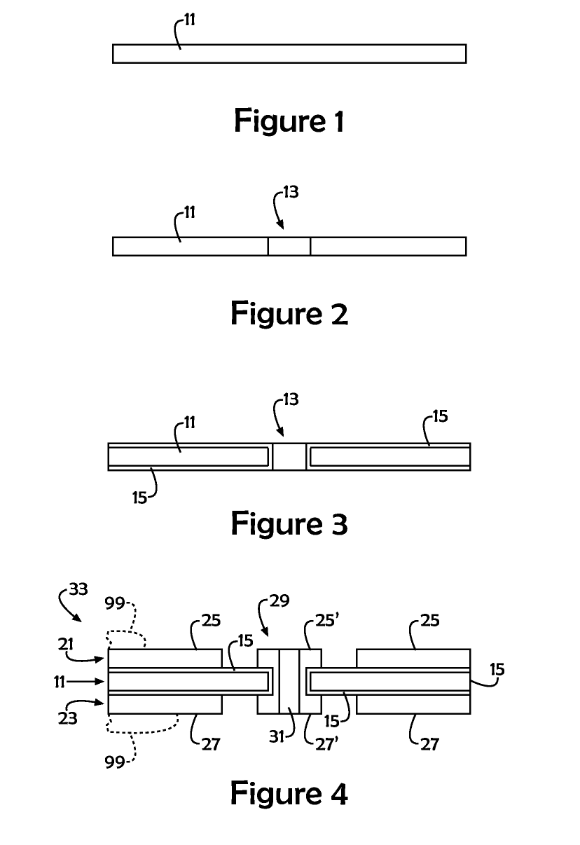

FIGS. 1 through 4 are partial side elevational views, in section, which illustrate the steps of forming a capacitive substrate for use in a circuitized substrate according to one aspect of this invention. It is to be understood that various alternatives to these steps are possible and thus within the scope of the invention.

In FIG. 1, an electrically conductive layer 11 is provided, preferably of copper or copper alloy and having a thickness of only about 0.5 mils to about 4.0 mils (a mil is understood to be 0.001 inch). In a preferred embodiment, layer 11 is provided from copper-Invar-copper (hereinafter also referred to as CIC), a known copper alloy used in forming conductive layers for circuitized substrates. In this particular embodiment, layer 11 may have a thickness of 1.4 mils.

In FIG. 2, layer 11 is provided with at least one hole 13 therein, which extends from the top surface to the underlying, opposing bottom surface of layer 11. In a preferred embodiment, hole 13 may include a diameter within the range of about 4 mils to about 100 mils. Hole 13 formation may be accomplished by drilling, punching or by an etching process which uses the application of photoresist to the conductive layer, exposure and development of selected portions of the photoresist, etching of holes, followed by photoresist removal. Although only one hole is shown for illustration purposes, it is understood that several may be provided in the conductive layer 11, depending on the operational requirements for the final substrate. In one example, several thousand holes 13 may be provided.

Following hole 13 formation, it may be desirable to micro-etch layer 11, including the internal surfaces of hole 13, to enhance the subsequent deposition process (described below), while removing any possible burrs that may have formed as a result of the hole formation procedure used (e.g., especially if drilling or punching is used). With respect to drilling and punching, micro-etching also provides a slight relief or radius on the hole edges to thereby enhance this subsequent deposition and relieve high stress points in the resulting layer.

In FIG. 3, a thin film layer of capacitance material 15 is applied onto the micro-etched layer 11, including on both opposing surfaces and within hole 13 (onto the walls defining this hole). As understood, the use of thin film layers represents a significant aspect of this invention. Such thin layer usage assures minimal increase in overall product dimensions (very important in microelectronic applications) while assuring increased capacitance density. As shown, this capacitive material is substantially of uniform thickness throughout, including on the sidewalls of the holes, and, as stated, very thin. Importantly, several capacitive materials may be used, including silicon oxide, titanium oxide, zirconium oxide, hafnium oxide, tantalum oxide, barium titanate, strontium titanate, lead zirconate titanate (PZT), lead magnesium niobate (PMN), lead magnesium niobate-lead titanate (PMN-PT), lead iron niobate (PFN) and lead zinc niobate (PZN), as well as combinations thereof. Of these, silicon oxide represents a preferred material. It is also possible that the thickness of the capacitor material on the side wall of the hole will be thicker than at the top and bottom surface. For example, sputtering one side at a time will expose the hole twice for the top and bottom surfaces. As a result, deposition will be thicker on the side wall of the hole than the top and bottom surfaces. In one example, thickness of the capacitor material on the side wall of the hole will be double that of the top and bottom surfaces.

Deposition of material 15 in thin film form may be accomplished by one of several methods, including sputtering (a particular example being reactive sputtering), chemical vapor deposition, metal organic chemical vapor deposition, anodizing, self assembly, solution coating on self assembled monolayer, ink-jet printing, sol-gel coating, thermal evaporation, pulsed laser deposition, solution coating and spin coating. It is also possible to use multiple methods to achieve desired thickness and properties. For example, sputtering and subsequent anodizing can be used. In a preferred embodiment, sputtering may be used to deposit the requisite thin film layer of silica. Briefly, sputtering is accomplished by introducing a pressurized gas into a vacuum chamber containing a negatively connected target source (source for film to be deposited from) and the substrate where the film will be deposited. One form of sputtering, reactive sputtering, may also be used and involves the use of a target material which is sputtered in the presence of a reactive gas (e.g., oxygen or nitrogen) to produce a desired compound. When sputtering, the gas creates a glow discharge whereby positive ions strike the target, and neutral target atoms are discharged by momentum transfer. The discharged atoms condense to form the desired film. Various machines are known for performing sputtering (as well as reactive sputtering) on materials such as CIC layer 11. Further description is not deemed necessary. Significantly, sputtering of the above materials enables the provision of layers having thicknesses of only about 0.01 micron up to 1.0 micron, whereas the subsequently listed processes for depositing these materials typically enable provision of layers having thicknesses slightly greater, usually from about one micron to about ten microns. Either way, extremely thin film layers are attainable.

A preferred silicon oxide material is obtainable from Evonik Degussa Corporation, located at Piscataway, N.J., and is sold under the product name AEROSIL fumed silica. In one example, this material may possess a surface area in the range of from about 50 to about 380 square meters per gram.

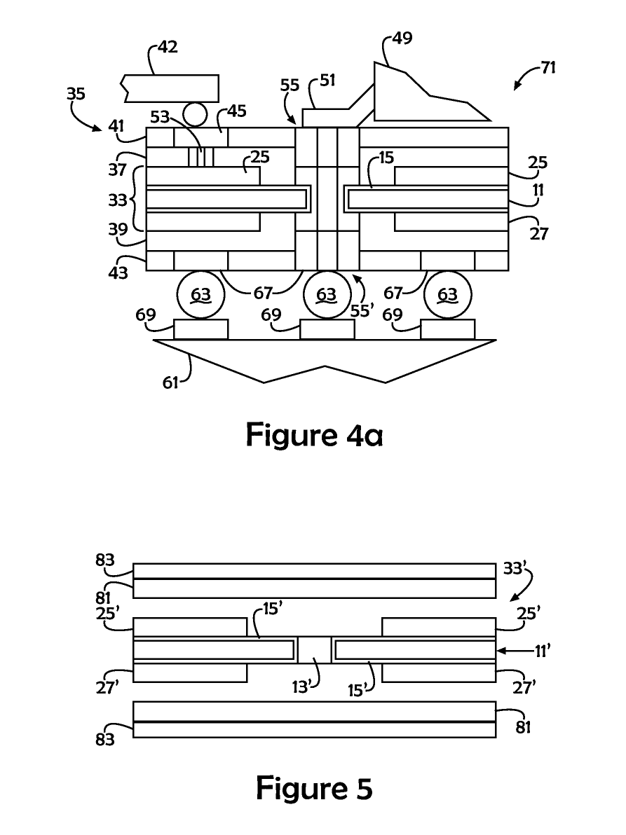

In FIG. 4, electrically conductive layers 21 and 23 are formed on opposite surfaces of the single layered structure of FIG. 3. Layers 21 and 23 are preferably copper or a combination of chromium (deposited first) and copper, and may also be applied by the aforementioned sputtering procedure or by plating, or even by a combination of both of these processes, followed by a conventional photolithography process known in the printed circuit board art during which a specified circuit pattern (i.e., individual conductive elements 25 and 27, which may comprise circuit lines and/or pads) is formed.

If plating, for example, the exposed surfaces of the capacitor material 15 may be “seeded” with a conventional metal, e.g., palladium or the aforementioned chromium, using a conventional operation known in PCB manufacturing. After this seeding, the chromium layering is plated with a layer of metal, e.g., copper. A preferred plating operation to accomplish this is electrolytic copper plating. Conductive layers 21 and 23 are preferably from about 5 microns to about 35 microns thick. This procedure will also result in the formation of a conductive thru-hole 29 due to the deposition of the conductive material within hole 13 (on material 15 therein) and on the opposed surfaces of material 15 on layer 11, resulting in formation of associated upper and lower pads 25′ and 27′. An opening 31 is then formed within the deposited conductive material, e.g., using drilling or punching, or it may also be formed by etching as part of the photolithographic process.

The result of the above processing is a capacitive substrate 33 wherein the outer conductive elements 25 and 27 to the left in FIG. 4, form a pair of capacitors with the common internal layer 11 having capacitive material 15 thereon. Additionally, layer 11 forms a capacitor with thru-hole 29. That is, element 25 and layer 11 form one capacitor, element 27 and layer 11 form a second capacitor, and the layer 11 and conductive material of thru-hole 29 form a third capacitor, all of which utilize capacitive material 15. Similar capacitors are formed with the elements 25 and 27 (and thru-hole 29) on the right in FIG. 4. The substrate 33 of FIG. 4 is thus able to provide up to six capacitors when used as part of a larger circuitized substrate, one example of which is shown in FIG. 4a. In one embodiment of the invention, comprising one or more of the above materials and having thicknesses in the above ranges, the formed capacitors are each capable of providing capacitance values of from about 7 nano-farads/sq. inch to about 2 micro-farads/sq. inch at this location of the final substrate.

The capacitive substrate 33 of FIG. 4 is now ready for further processing, including, for example, being formed as part of a chip carrier, multilayered printed circuit board or other circuitized substrate structure wherein additional dielectric (e.g., pre-preg), conductive (e.g., copper) and pre-formed signal and/or power core layers may be added to the assembly and joined together. As understood from the teachings herein, the substrate 33 is also adapted for being formed into an interconnector structure for interconnecting various electronic components, including semiconductor chips, printed circuit boards, chip carrier packages, etc.

In FIG. 4a, capacitive substrate (actually a parallel capacitor structure) is shown as being internally positioned between added dielectric (e.g., conventional glass-filled epoxy resin) layers 37 and 39, and thus an integral part of a larger circuitized substrate 35. It must be understood that the particular configuration shown for substrate 35 is not intended to limit this invention since many different combinations of dielectric and conductive layers may be used in addition to the common capacitive substrate structure. The added dielectric and conductive layers may be added to this structure using conventional lamination and photolithographic processing known in the art. In this example, circuitized substrate 35 further includes these added layers 37 and 39, in addition to external circuit layers 41 and 43. Circuit layer 41 includes at least one (and preferably several) conductor pad(s) 45 which is (are) coupled to a semiconductor chip 42 or similar electrical component. Chip 42 is bonded to the conductors of the upper circuit layer 41 by controlled collapse chip connection (C4) methodology, known in the art. Such upper conductors, or at least those designated to couple to the chip 42, may be of a high density pattern, as defined above. Several electrical components may be mounted on and electrically coupled to this upper portion of substrate 35, another example being a module 49 having externally projecting leads 51 (only one shown in FIG. 4A). Pad 45 is coupled to element 25 of the capacitive substrate by a thru-hole 53 of conventional construction. Lead 51 is connected, e.g., soldered, to the upper portion of another thru-hole 55, the upper portion thereof being formed atop the already provided thru-hole 29 of the capacitive substrate. A similar lower thru-hole 55′ is also formed on the lower part of thru-hole 29 to thereby form a thru-hole which extends through the entirety of substrate 35.

The lower circuit layer 43 of substrate 35 is adapted for being electrically coupled to a host circuitized substrate 61 such as a larger PCB, preferably utilizing solder ball 63 connections which bond respective pads or conductor members 67 of the circuit layer to corresponding pads 69 on the upper surface of the hosting substrate. The assembly including the circuitized substrate 35 and at least one electrical component (i.e., chip 42) thus forms an electronic package 71 as defined above. The resulting assembly shown in FIG. 4a, including the package 71 and the hosting substrate 61, may in turn form part of an information handling system, e.g., personal computer.

The substrate 35 of FIG. 4a includes many different possible combinations of circuits, and is thereby able to meet many design requirements for such packages using same. Such combinations may include several different circuits requiring capacitors as part thereof, and the invention is thus able to also satisfy many of these particular requirements. For example, a capacitor is formed as part of the circuit including chip 41, pad 45, thru-hole 53, conductive element 25, and conductive layer 11. A capacitor is also formed as part of the circuit including module 49, lead 51, upper thru-hole 55, thru-hole 29 and conductive layer 11. Many other circuits may be formed in the FIG. 4a assembly to include capacitors, e.g., forming a thru-hole connection between lower pad 67 (to the right) and lower conductive element 27. Using the materials and dimensions defined herein, the resulting electronic package 71 was able to provide high frequency signal speeds within a frequency range of from about 3.0 to about 10.0 gigabits per second (GPS) and possibly even faster.

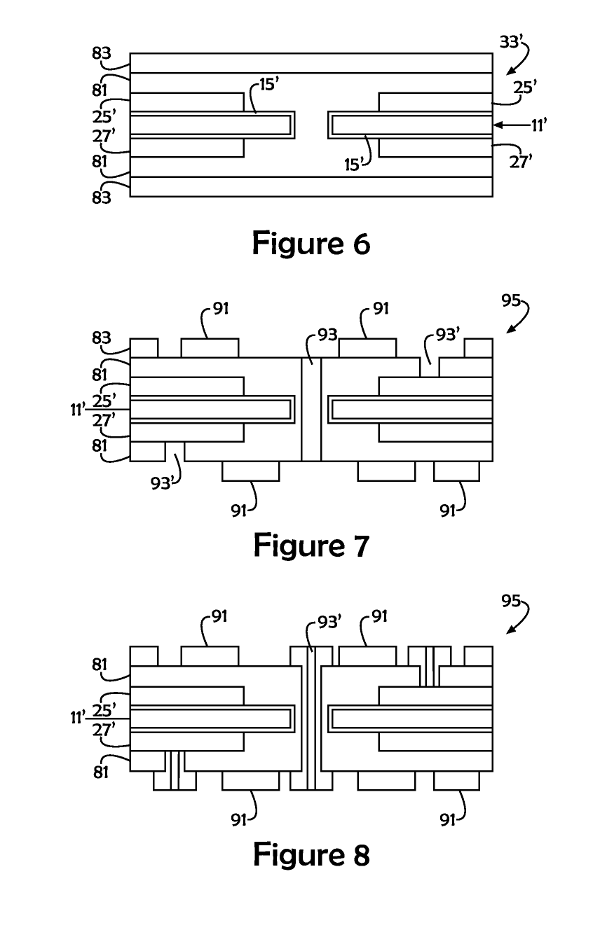

FIGS. 5 through 8 illustrate the steps of forming a circuitized substrate including a capacitive substrate 33′, similar to that of the substrate 33 of FIG. 4 but excluding the thru-hole 29, according to one embodiment of this invention. In FIG. 5, the capacitive substrate 33′ is positioned between two opposing layers of dielectric material 81 each having a conductive layer 83 thereon. The conductive layers are located externally of the dielectric layers. The dielectric material 81 may be one of those cited above, and the conductive material for layers 83 one also of those cited above. In one example, the dielectric material may be fiberglass-reinforced or non-reinforced epoxy resin, and the conductive material copper or copper alloy.

In FIG. 6, the three multi-layered elements of FIG. 5 are bonded together, preferably utilizing conventional lamination processing known in the art. In one example, a pressure of from about 500 pounds per square inch (PSI) to about 700 PSI, a temperature of from about 180 degrees C. to about 200 degrees C., and a time period of about 60 minutes to about 120 minutes may be used to bond all of the elements shown in FIG. 5. Significantly, the inwardly facing dielectric materials 81 are so heated during this process that these flow into and fill the opening 13′ having capacitive material 15′ thereon. This material also covers and securely bonds to the exposed surfaces of material 15′ on the conductive layer 11′ which project beyond the end segments of the conductive elements 25′ and 27′ of the capacitive substrate 33′. Despite the high temperatures and pressures required for this lamination, the thin film layers of material 15′ are not harmed but fully retain their capacitive properties. This is considered particularly significant due to the relatively thin nature of the many elements being subjected to such pressures and temperatures.

In FIG. 7, the outer conductive layers 83 are subjected to circuitization processing, e.g., using conventional photolithographic processes, to form desired patterns (i.e., conductors 91) on both upper and lower surfaces of the FIG. 7 structure. This patterning results in the removal of selected parts of the conductive layering, as shown. In addition, a hole 93 is formed through the dielectric material, as are holes 93′ in selected parts of the outer portion of the dielectric, to exposed corresponding surfaces of the internal conductive elements 25′ and 27′. Such hole formation may be accomplished using drilling, punching or by an etching process which uses the application of photoresist to the conductive layer (81 and/or 83), exposure and development of selected portions of the photoresist, etching of holes, followed by photoresist removal. To connect layer 11 (not shown in FIG. 7), it is necessary to drill through layer 11. The subsequently plated through hole will connect layer 11 to make the capacitor operational from an external surface.

In FIG. 8, the walls of the formed holes 93 and 93′ are plated with conductor material to form thru-holes, the larger thru-hole in the center extending entirely through the structure while those to the internal conductive segments extending only to same. In one embodiment, the internal walls of each hole may be “seeded” with a conventional metal, e.g., palladium, using a conventional operation known in PCB manufacturing. After seeding, the holes are plated with a layer of metal, e.g., copper. A preferred plating operation to accomplish this is electrolytic copper plating. The resulting structure shown in FIG. 8 is a circuitized substrate 95 including many of the features of substrate 35 in FIG. 4a. Substrate 95 may then be mounted on and electrically coupled to a host substrate and also have electrical components mounted on its upper surface, as is substrate 35.

As understood from the foregoing, the capacitive substrates 33 and 33′ of FIGS. 4 and 5 and may be incorporated into a larger electrical structure such as a printed circuit board or a chip carrier (typically much smaller than the usual printed circuit board) designed for accommodating one or more chips as part thereof) for placement on a hosting printed circuit board. The capacitor structure defined herein may be modified through the addition of desired conductive and/or dielectric layers prior to such incorporation or as an entirely separate interconnect structure for coupling two separated electronic components (including, for example, printed circuit boards, the aforementioned chip carriers (e.g., when one is desirably coupled onto a printed circuit board), and even just semiconductor chips (e.g., when coupling one onto the carrier's substrate or another, larger circuit board)). The invention as described herein is thus capable of many uses and is adaptable to a multitude of different circuit patterns. Still further, while the invention utilizes thin film capacitors as integral parts thereof, it is also within the scope of the teaching provided herein to utilize thick film layers of capacitive material in combination with one or more thin film layered capacitors. For example, in the embodiment of FIG. 4, it may be possible to deposit thick film layers of capacitive material 99 (shown in phantom), including layers of the same capacitive material as used for the thin film layers defined above) onto the outer surfaces of conductive elements 25 and/or 27, and then provide the desired dielectric layers and associated electrical connections, i.e., to one or more external conductors 45 and/or 67. The use of thicker capacitors may be acceptable if less stringent dimensional requirements are necessary for the final circuitized substrate and electronic package products.

Low dielectric constant is another advantage of silica to blend with the substrate dielectric without significant interference of signal performance and the impedance target. Silica acts as a capacitance layer within the electrode and acts as a dielectric in the rest of the layer. Most of the dielectrics including resin coated copper (RCC) pre-preg are silica filled and/or glass reinforced resin and their dielectric constant is dominated by silica and glass. So it will be easy for a silica layer to blend with a pre-preg or RCC without significantly compromising signal performance or the impedance target.

Since other modifications and changes varied to fit particular operating requirements and environments will be apparent to those skilled in the art, the invention is not considered limited to the example chosen for purposes of this disclosure, and covers all changes and modifications which do not constitute departures from the true spirit and scope of this invention.

Having thus described the invention, what is desired to be protected by Letters Patent is presented in the subsequently appended claims.

1. A circuitized substrate comprising:
a capacitive substrate including at least one electrically conductive layer, a low dielectric constant silica-based ceramic thin film layer of capacitor material disposed on said at least one electrically conductive layer, and at least one electrically conductive element positioned on a first surface of said low dielectric constant silica-based ceramic thin film layer adjacent said at least one electrically conductive layer; and
at least one low dielectric constant organic-based dielectric layer positioned on said capacitive substrate, said at least one electrically conductive layer, said low dielectric constant silica-based ceramic thin film layer, and said at least one electrically conductive element forming a first capacitor within said circuitized substrate during operation thereof, said low dielectric constant silica-based ceramic thin film layer blending with said at least one low dielectric constant organic-based dielectric layer and acting as a single dielectric layer without significant interference of signal performance.

2. The circuitized substrate of claim 1, further comprising a second low dielectric constant silica-based ceramic thin film layer and including a second electrically conductive element positioned thereon adjacent said at least one electrically conductive layer and low dielectric constant organic-based dielectric layer, said second electrically conductive element, said second low dielectric constant silica-based ceramic thin film layer and said at least one electrically conductive layer forming a second capacitor within said circuitized substrate during operation thereof, said second low dielectric constant silica-based ceramic thin film layer without said second electrically conductive layer blending with said second low dielectric constant organic-based dielectric layer and acting as a single dielectric without significant interference of signal performance.

3. The circuitized substrate of claim 2, further including a hole within said at least one conductive layer having at least one internal surface, said thin film layer being positioned on said at least one internal surface of said hole, and electrically conductive material positioned on said thin film layer of capacitor material positioned on said at least one internal surface of said hole, said electrically conductive material, said thin film layer positioned on said at least one internal surface of said hole and said at least one conductive layer forming a third capacitor within said circuitized substrate during operation of said circuitized substrate.

4. The circuitized substrate of claim 3, wherein the capacitance of each of said first, second and third capacitors is within the range of from about 7 nano-farads/square inch to about 2 micro-farads/square inch.

5. The circuitized substrate of claim 1, further including a hole within said at least one conductive layer having at least one internal surface, said thin film layer being positioned on said at least one internal surface of said hole, and electrically conductive material positioned on said thin film layer positioned on said at least one internal surface of said hole, said electrically conductive material, said thin film layer of capacitor material positioned on said at least one internal surface of said hole and said at least one conductive layer forming a second capacitor within said circuitized substrate during operation of said circuitized substrate.

6. The circuitized substrate of claim 1, wherein said thin film layer of capacitor material is selected from the group consisting of silicon oxide, titanium oxide, zirconium oxide, hafnium oxide, tantalum oxide, barium titanate, strontium tinanate, lead zirconate titanate, lead magnesium niobate, lead magnesium niobate-lead titanate, lead iron niobate, lead zinc niobate, and combinations thereof.

7. The circuitized substrate of claim 1, wherein the capacitance of said first capacitor is within the range of from about 7 nano-farads/square inch to about 2 micro-farads/square inch.

8. The circuitized substrate of claim 1, further including at least one electrical component positioned on said circuitized substrate and electrically coupled to said first capacitor within said circuitized substrate, said circuitized substrate and said at least one electrical component comprising an electronic package.

9. A method of making a circuitized substrate comprising:
providing an electrically conductive layer including upper and lower opposing surfaces;
depositing a thin film layer of capacitor material on said upper and lower opposing surfaces of said electrically conductive layer;
bonding a pair of electrically conductive elements to said thin film layer, a first of said electrically conductive elements located on said capacitor material on said upper opposing surface of said electrically conductive layer and a second of said electrically conductive elements located on said capacitor material on said lower opposing surface of said electrically conductive layer to form a capacitive substrate including said electrically conductive layer, said thin film layer on said upper and lower opposing surfaces of said electrically conductive layer and said electrically conductive elements; and
bonding at least one dielectric layer onto said capacitive substrate to substantially cover at least one of the group: said first electrically conductive element and second electrically conductive element.

10. The method of claim 9, wherein said depositing of said thin film layer is accomplished by sputtering.

11. The method of claim 9, wherein said depositing of said thin film layer is accomplished by a process selected from the group: chemical vapor deposition, metal organic chemical vapor deposition, anodizing, self assembly, solution coating on self assembled monolayer, ink-jet printing, sol-gel coating, thermal evaporation, pulsed laser deposition, solution coating, spin coating, and combinations thereof.

12. The method of claim 9, wherein said bonding of said pair of electrically conductive elements to said thin film layer is accomplished by at least one of the group: sputtering, plating, and electrolytic plating.

13. The method of claim 9, further including forming a hole within said electrically conductive layer extending through said electrically conductive layer from said upper opposing surface to said lower opposing surface, said depositing of said thin film layer on said upper and lower opposing surfaces of said electrically conductive layer including depositing said capacitor material on the walls of said hole.

14. The method of claim 9, wherein said bonding said at least one dielectric layer onto said capacitive substrate to substantially cover said first and/or second electrically conductive elements is accomplished by lamination.

15. A method of making a circuitized substrate comprising:
providing an electrically conductive layer including upper and lower opposing surfaces;
forming a hole having walls within said electrically conductive layer extending through said electrically conductive layer from said upper opposing surface to said lower opposing surface;
depositing a thin film layer of capacitor material on said upper and lower opposing surfaces of said electrically conductive layer and onto the walls of said hole;
bonding a pair of electrically conductive elements to said thin film layer, a first of said electrically conductive elements located on said capacitor material on said upper opposing surface of said electrically conductive layer and a second of said electrically conductive elements located on said capacitor material on said lower opposing surface of said electrically conductive layer to form a capacitive substrate including said electrically conductive layer, said thin film layer on said upper and lower opposing surfaces of said electrically conductive layer and said electrically conductive elements; and
bonding first and second dielectric layers each having a conductive layer thereon onto said capacitive substrate so as to force portions of said dielectric material of said first and second dielectric layers into said hole within said electrically conductive layer, other portions of said dielectric material of said first and second dielectric layers substantially covering said first and second electrically conductive elements.

16. The method of claim 15, wherein said depositing of said thin film layer is accomplished by a process selected from the group: consisting of chemical vapor deposition, metal organic chemical vapor deposition, ink-jet printing, sol-gel coating, thermal evaporation, pulsed laser deposition, sputtering, solution coating and spin coating.

17. The method of claim 15, wherein said bonding of said pair of electrically conductive elements to said thin film layer is accomplished by at least one of the group: sputtering, plating, and electrolytic plating.

18. The method of claim 15, wherein said forming of said hole having said walls within said electrically conductive layer is accomplished by a process selected from the group: drilling, punching, and etching.
